(19) United States
(12) Patent Application Publication
(10) Pub. No.: US 2023/0232548 A1
(43) Pub. Date: Jul. 20, 2023

(54) ELECTRICAL JUNCTION BOX

(71) Applicant: Sumitomo Wiring Systems, Ltd., Yokkaichi-shi, Mie (JP)

(72) Inventors: Yuya MATSUO, Yokkaichi-shi, Mie (JP); Akihiro ODA, Yokkaichi-shi, Mie (JP); Tatsuya DAIDOJI, Yokkaichi-shi, Mie (JP); Noriko OKAMOTO, Yokkaichi-shi, Mie (JP); Ryoma HAMADA, Yokkaichi-shi, Mie (JP)

(21) Appl. No.: 17/904,244

(22) PCT Filed: Feb. 9, 2021
(86) PCT No.: PCT/JP2021/004706

§ 371 Date: Mar. 31, 2023

(30) Foreign Application Priority Data
Feb. 21, 2020 (JP) 2020-028503

(51) Int. Cl. H05K 5/00; H01H 85/48; H05K 7/02

(52) U.S. Cl. CPC H05K 5/0047; H01H 85/48; H05K 7/026

(57) ABSTRACT

Provided is an electrical junction box including a substrate on which fixed fuses and replaceable fuses are mounted. The substrate includes a first part to which the fixed fuses are soldered, and a second part that excludes the first part. The first part and the second part are separable from each other.

### CROSS-REFERENCE TO RELATED APPLICATIONS

This application is the U.S. national stage of PCT/JP2021/004706 filed on Feb. 9, 2021, which claims priority of Japanese Patent Application No. JP 2020-028503 filed on Feb. 21, 2020, the contents of which are incorporated herein.

### TECHNICAL FIELD

The present disclosure relates to an electrical junction box.

### BACKGROUND

Conventionally, vehicular electrical junction boxes for electrically connecting a battery and various electrical components have become widely spread. Many vehicles are provided with an electrical junction box that is disposed between a power supply and electrical components to supply power to them. An electrical junction box houses a substrate assembly in which components such as busbars and fuses are mounted on a substrate.

Meanwhile, JP 2016-220276A discloses an electrical junction box that includes a power module for causing a current to flow through a voltage circuit or interrupting the current flow, the power module being screwed to or held between busbars so as to be detachable.

As fuses for protecting a circuit when an overcurrent flows, there are replaceable fuses and fixed fuses, which are used depending on the application. Replaceable fuses and fixed fuses are mounted on a corresponding substrate by different methods.

Replaceable fuses are fuses that are from the beginning expected to be replaced at some time, and are detachably connected to a substrate via holding members for temporarily holding the fuses. Also, fixed fuses are fuses that are originally not intended to be replaced, and are directly fixed to a substrate by, for example, soldering since they do not need to be replaced.

On the other hand, due to some reason, a blowout of a fixed fuse may occur. However, since the fixed fuse is fixed to the substrate, it is not easy to replace only this fuse, but the entire substrate assembly needs to be replaced. Thus, replacing the entire substrate assembly although only a fixed fuse has been blown out is a waste of resources, and results in environmental destruction.

However, JP 2016-220276A discloses a case where the power module is configured to be detachable as in the case of replaceable fuses, but does not mention a case where the power module is fixed to a substrate by soldering as in the case of fixed fuses. Accordingly, JP 2016-220276A cannot solve the above-described problems.

Therefore, an object of the present disclosure is to provide an electrical junction box that can handle a blowout of a fixed fuse easily and at low cost.

### SUMMARY

An electrical junction box according to an embodiment of the present disclosure relates to an electrical junction box including a substrate on which fuses are mounted, wherein the substrate includes a first part to which the fuses are soldered, and a second part that excludes the first part, and the first part and the second part are separable from each other.

### Advantageous Effects

According to the present disclosure, it is possible to handle a blowout of a fixed fuse soldered to a substrate easily and at low cost.

### BRIEF DESCRIPTION OF DRAWINGS

FIG. 1 is a perspective view illustrating an outer appearance of an electrical junction box according to Embodiment 1.

FIG. 2 is a perspective view illustrating a substrate assembly to be housed in a case member of the electrical junction box according to Embodiment 1.

FIG. 3 is a longitudinal cross-sectional view of the substrate assembly taken along a line III-III in FIG. 2.

FIG. 4 is a diagram illustrating a state of the electrical junction box according to Embodiment 1 where a first part is separated from a second part.

FIG. 5 is a perspective view illustrating an outer appearance of an electrical junction box according to Embodiment 2.

FIG. 6 is a plane view of the electrical junction box according to Embodiment 2.

FIG. 7 is a perspective view illustrating an outer appearance of an electrical junction box according to Embodiment 3.

FIG. 8 is a perspective view illustrating an outer appearance of an electrical junction box according to Embodiment 4.

### DETAILED DESCRIPTION OF PREFERRED EMBODIMENTS

First, embodiments of the present disclosure will be listed and described. Also, at least some of the embodiments described below may be combined with each other as appropriate.

### First Embodiment

An electrical junction box according to a first embodiment of the present disclosure relates to an electrical junction box including a substrate on which fuses are mounted, wherein the substrate includes a first part to which the fuses are soldered, and a second part that excludes the first part, and the first part and the second part are separable from each other.

According to the first embodiment, since the first part and the second part are configured to be separable from each other, if, for example, any of the fuses soldered to the first part is blown out, it is possible to separate and replace the first part. Accordingly, it is possible to handle a blowout easily and at low cost, without replacing the entire substrate.

### Second Embodiment

In the electrical junction box according to a second embodiment of the present disclosure, the first part is arranged in an edge portion of the substrate.

According to the second embodiment, since the first part is arranged in an edge portion of the substrate, it is easy to separate the first part.

### Third Embodiment

The electrical junction box according to a third embodiment of the present disclosure further includes a housing in which the substrate is housed, wherein the housing includes an outlet for removing the first part.

According to the third embodiment, since the housing includes the outlet, if, for example, any of the fuses soldered to the first part is blown out, it is possible to remove and replace the first part through the outlet, without disassembling the housing. Accordingly, the operation for replacing the first part is easy.

### Fourth Embodiment

The electrical junction box according to a fourth embodiment of the present disclosure includes a lid member for opening and closing the outlet.

According to the fourth embodiment, since the lid member covers the outlet and can open and close, it is possible to prevent dust or the like from entering the housing through the outlet. Thus, if, for example, any of the fuses soldered to the first part is blown out, a user can open the lid member and replace the first part through the outlet.

### Fifth Embodiment

In the electrical junction box according to a fifth embodiment of the present disclosure, the lid member is at least partially transparent.

According to the fifth embodiment, since the lid member is at least partially transparent, the user can check, through such a transparent part of the lid member, whether or not any fuse has been blown out.

### Sixth Embodiment

In the electrical junction box according to a sixth embodiment of the present disclosure, the outlet is formed at a position that corresponds to the first part.

According to the sixth embodiment, since the outlet is formed in the housing at a position corresponding to the first part located inside, it is possible to easily replace the first part through the outlet.

### Seventh Embodiment

The electrical junction box according to a seventh embodiment of the present disclosure further includes a holding member for holding the first part on the second part, wherein the holding member is configured to electrically connect the first part to the second part.

According to the seventh embodiment, the first part is held on the second part by the holding member, and is electrically connected to the second part. That is to say, the holding member functions as a holding member as well as an electrical connector between the first part and the second part. This makes it possible to reduce the number of components of the electrical junction box, and to downsize the electrical junction box.

The following will describe the electrical junction box according to embodiments of the present disclosure with reference to the drawings. Note that the present disclosure is not limited to the examples but is defined by the claims, and all modifications within the meaning and scope equivalent to the claims are intended to be included.

### Embodiment 1

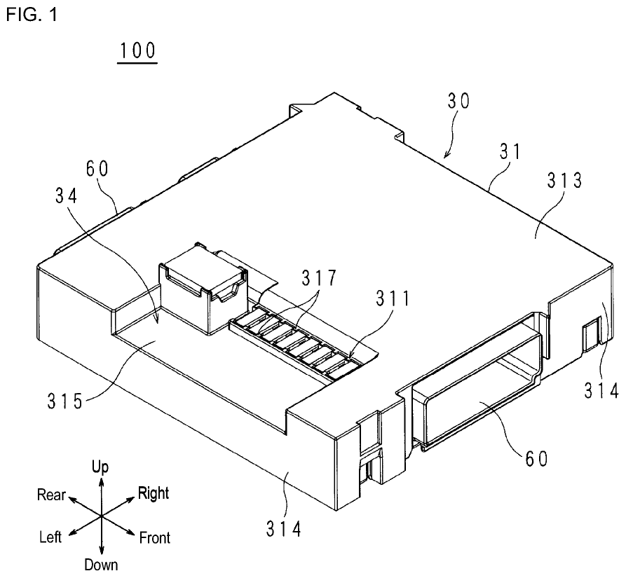

FIG. 1 is a perspective view illustrating an outer appearance of an electrical junction box 100 according to Embodiment 1. The electrical junction box 100 is a so-called vehicular junction box provided with fuses.

In the present embodiments, for convenience, “front”, “rear”, “left”, “right”, “up”, and “down” of the electrical junction box 100 are defined based on the front-rear direction, left-right direction, and up-down direction of the drawings. The following description will be given based on the front-rear direction, the left-right direction, and the up-down direction thus defined.

The electrical junction box 100 includes a case member 30 that has a flat cuboid shape, and the case member 30 houses a later-described substrate assembly 20.

The case member 30 includes a substantially rectangular ceiling plate 313, side plates 314 extending perpendicularly downward from side edges of the ceiling plate 313, and a bottom plate (not shown) opposing to the ceiling plate 313. A recess 34 is formed in the region of the left-side edge of the case member 30.

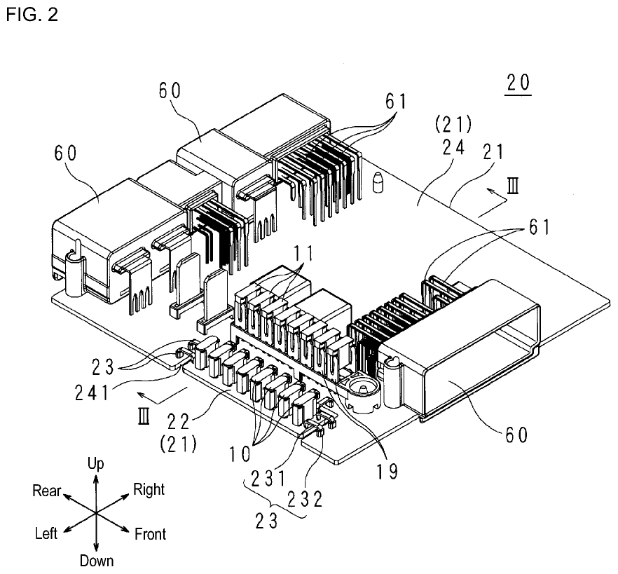

FIG. 2 is a perspective view illustrating the substrate assembly 20 to be housed in the case member 30 of the electrical junction box 100 according to Embodiment 1.

The substrate assembly 20 is attached to the bottom plate of the case member 30. The substrate assembly 20 includes a substrate 21 that covers substantially the entire surface of the bottom plate, and circuit components mounted on the upper surface of the substrate 21. That is to say, the substrate 21 faces the bottom plate and the ceiling plate 313 of the case member 30.

Also, the substrate 21 is provided with one connection port 60 in a front-side edge portion, and two connection ports 60 in a rear-side edge portion. The connection ports 60 are connected to the substrate 21 via connection terminals 61 that are bent in an L shape. The side plates 314 of the case member 30 on the front and rear sides have through holes that penetrate the corresponding side plate 314, and the connection ports 60 protrude to the outside of the case member 30 via the through holes formed in the side plates 314.

Furthermore, two types of fuses, namely, a plurality of replaceable fuses 11 and a plurality of fixed fuses 10, are mounted on the substrate 21. The plurality of fixed fuses 10 are lined up along the left-side edge of the substrate 21, and the plurality of replaceable fuses 11 are lined up on the side closer to a central portion of the substrate 21 than the fixed fuses 10 are. The fixed fuses 10 are mounted at an interval greater than the interval at which the replaceable fuses 11 are mounted.

The replaceable fuses 11 are fuses that are from the beginning expected to be replaced at some time, and are held on the substrate 21 so as to be detachable. The fixed fuses 10 are fuses that are not intended to be replaced, and are fixed to the substrate 21.

The replaceable fuses 11 are connected, via holding terminals 19, to a printed wiring board (not shown) or the like formed on the substrate 21. A plurality of holding terminals 19 are lined up in the front-rear direction. Each holding terminal 19 has a pair of U-shaped pinching parts that stand upward from the substrate 21 at positions apart from each other in the left-right direction.

Each replaceable fuse 11 is attached spanning the space between the pair of pinching parts of the corresponding holding terminal 19, and is detachably held. That is to say, the replaceable fuse 11 can easily be replaced by being inserted into and retracted from the holding terminal 19.

In contrast, the fixed fuses 10 are fixed to the printed wiring board of the substrate 21 by soldering. Therefore, the fixed fuses 10 cannot easily be replaced.

A replacement window 311 is formed in a bottom 315 of the recess 34 of the case member 30. The replacement window 311 penetrates the bottom 315 in the thickness direction, and is formed at a position matching the positions of the plurality of replaceable fuses 11 when viewed in the thickness direction (up-down direction) of the case member 30.

As described above, since the plurality of replaceable fuses 11 are lined up in a row, the replacement window 311 has the shape of a rectangle whose longitudinal direction conforms to the direction in which the plurality of replaceable fuses 11 are lined up. A pair of guide frames 317 are provided on the bottom 315 while extending along the long sides of the replacement window 311. The guide frames 317 are comb-shaped members with the same number of grooves as the number of the replaceable fuses 11.

All of the replaceable fuses 11 are exposed to the outside of the case member 30 via the replacement window 311. Accordingly, when a replaceable fuse 11 is blown out, a user can replace this replaceable fuse 11 through the replacement window 311. At this time, the insertion and removal of the replaceable fuse 11 are guided by the guide frames 317.

The substrate 21 is constituted by a first part 22 to which the plurality of fixed fuses 10 are fixed by soldering, and a second part 24 to which the circuit components (including the replaceable fuses 11) other than the fixed fuses 10 are mounted. The substrate 21 is rectangular as a whole, and the first part 22 is arranged in the left-side edge portion of the substrate 21. The second part 24 is the remaining portion of the substrate 21 that excludes the first part 22, and accounts for a large portion of the substrate 21.

The second part 24 has, on the left side thereof, a strip-shaped cutout 241 elongated in the front-rear direction. The first part 22 has a strip shape that corresponds to the cutout 241 of the second part 24. The plurality of fixed fuses 10 are lined up in the longitudinal direction of the first part 22, and are fixed by soldering to predetermined positions on the first part 22.

When the substrate assembly 20 (substrate 21) is attached to the bottom plate of the case member 30, the first part 22 is arranged inside the cutout 241 of the second part 24. Here, the first part 22 and the second part 24 are coplanar, and the first part 22 is held by the second part 24.

The electrical junction box 100 according to Embodiment 1 has a configuration in which the first part 22 can be separated from the second part 24. Detailed description will be given below.

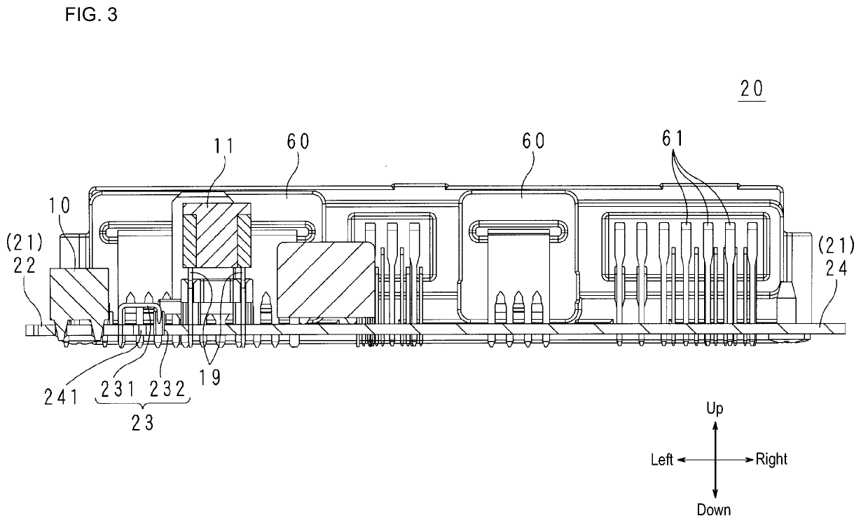

FIG. 3 is a longitudinal cross-sectional view of the substrate assembly 20 taken along a line III-III in FIG. 2.

The first part 22 is held by the second part 24 with holding members 23, and is removable. Each holding member 23 is constituted by a bridge terminal 231 and a terminal block 232. The bridge terminals 231 are provided on the first part 22 and the terminal blocks 232 are provided on the second part 24.

The bridge terminals 231 are substantially semicircular ring-shaped, and are provided along three, of the four side edges of the first part 22, that face the second part 24. One end portion of each bridge terminal 231 is connected to a circuit provided on the first part 22 by, for example, soldering, and another end portion of the bridge terminal 231 protrudes outward from the edge of the first part 22. The bridge terminals 231 are made of an electrical conducting material, and are electrically connected to the plurality of fixed fuses 10.

A plurality of terminal blocks 232, which are tubular, are provided along the side edge of the cutout 241. The terminal blocks 232 correspond to the other end portions of the respective bridge terminals 231, and are provided at positions corresponding to the respective bridge terminals 231. The terminal blocks 232 are electrically connected to the circuit components provided on the second part 24 via, for example, printed wiring formed on the second part 24.

When the substrate assembly 20 (substrate 21) is attached to the bottom plate of the case member 30, the first part 22 is arranged inside the cutout 241 of the second part 24, and the bridge terminals 231 are here engaged with the corresponding terminal blocks 232 so as to bridge the space between the first part 22 and the second part 24.

That is to say, the other end portions of the bridge terminals 231 are pressed into the corresponding terminal blocks 232, and are externally fitted to the terminal blocks 232. At this time, the bridge terminals 231 are electrically connected to the terminal blocks 232.

As a result of the plurality of bridge terminals 231 engaging with the corresponding terminal blocks 232 in this way, the first part 22 is held on the second part 24 while being coplanar therewith, and the first part 22 and the second part 24 form one piece. At the same time, the first part 22 and the second part 24 are electrically connected to each other via the holding members 23.

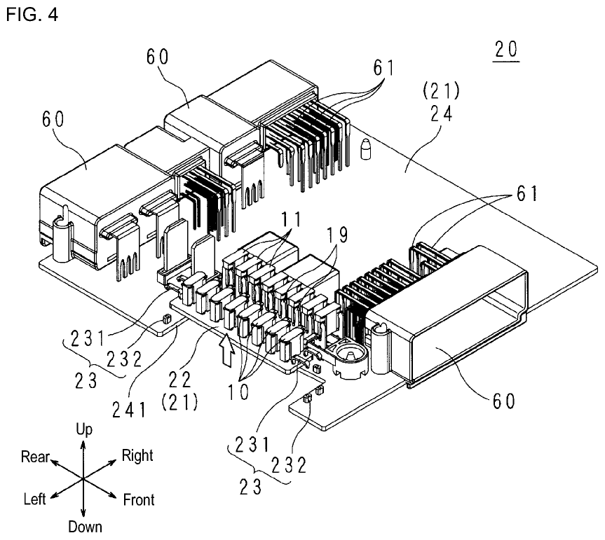

On the other hand, when separating the first part 22 from the second part 24, it is sufficient for a user to disengage the bridge terminals 231 from the terminal blocks 232. FIG. 4 is a diagram illustrating a state of the electrical junction box 100 according to Embodiment 1 where the first part 22 is separated from the second part 24.

The user pulls the other end portions of the bridge terminals 231 out of the terminal blocks 232 with which the bridge terminals 231 are engaged, and disengages the bridge terminals 231 from the terminal blocks 232. When all of the bridge terminals 231 are disengaged from the corresponding terminal blocks 232, the user can raise the first part 22 in the thickness direction (direction of a white arrow in FIG. 4) of the second part 24, and can separate the first part 22 from the second part 24.

If the first part 22 is moved in a direction along the surface of the second part 24 and is separated from the second part 24, a trouble may occur, such as the bridge terminals 231 being caught by adjacent terminal blocks 232, and thus it is preferable to raise the first part 22 in the thickness direction of the second part 24 and separate the first part 22 from the second part 24.

With the above-described configuration, the electrical junction box 100 according to Embodiment 1 can be subjected to easy and low-cost maintenance.

That is to say, the fixed fuses 10, which are originally not intended to be replaced, are fixed to the substrate 21 by, for example, soldering, since they do not need to be replaced, but a blowout of a fixed fuse 10 may occur due to some reason.

In contrast, in the electrical junction box 100 according to Embodiment 1, the fixed fuses 10 are fixed to the first part 22, and the first part 22 can be separated from the substrate 21 (second part 24). Accordingly, if any fixed fuse 10 is blown out, only the first part 22, instead of the entire substrate assembly 20, needs to be replaced. Thus, it is possible to handle a blowout of a fixed fuse 10 easily and at low cost, making it also possible to prevent a waste of resources.

Furthermore, in the electrical junction box 100 according to Embodiment 1, the first part 22 is held on the second part 24 by the holding members 23, and the first part 22 is electrically connected to the second part 24. That is to say, the holding members 23 function as holding members as well as electrical connectors, thus eliminating the need to provide separate holding members and electrical connectors. This makes it possible to reduce the number of components of the electrical junction box 100, and to downsize the electrical junction box 100.

### Embodiment 2

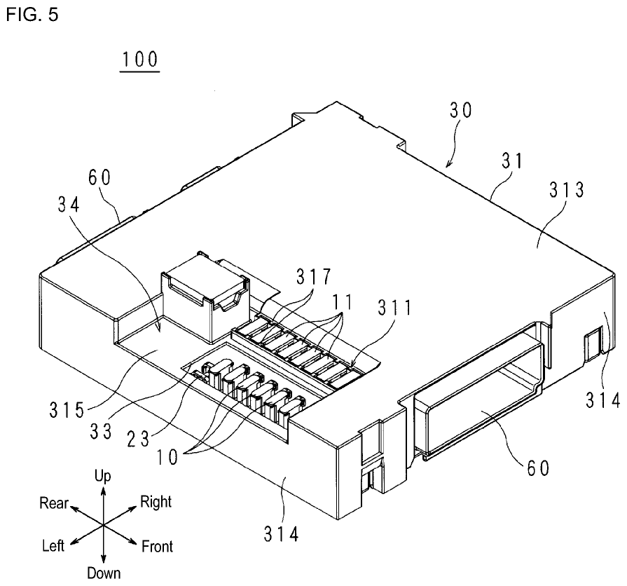

FIG. 5 is a perspective view illustrating an outer appearance of an electrical junction box 100 according to Embodiment 2.

Similar to Embodiment 1, the electrical junction box 100 according to Embodiment 2 includes a case member 30, and the case member 30 includes a substrate 21, a plurality of replaceable fuses 11 held on the substrate 21 so as to be detachable, and a plurality of fixed fuses 10 fixed to the substrate 21 by soldering.

Also, similar to Embodiment 1, the substrate 21 is constituted by a first part 22 and a second part 24, and the first part 22 is held on the second part 24 by holding members 23 (see FIG. 2), and is electrically connected to the second part 24.

Furthermore, a replacement window 311 for replacement of the replaceable fuses 11 is formed in a bottom 315 of the case member 30 at a position matching the positions of the plurality of replaceable fuses 11 when viewed in the thickness direction (up-down direction) of the case member 30.

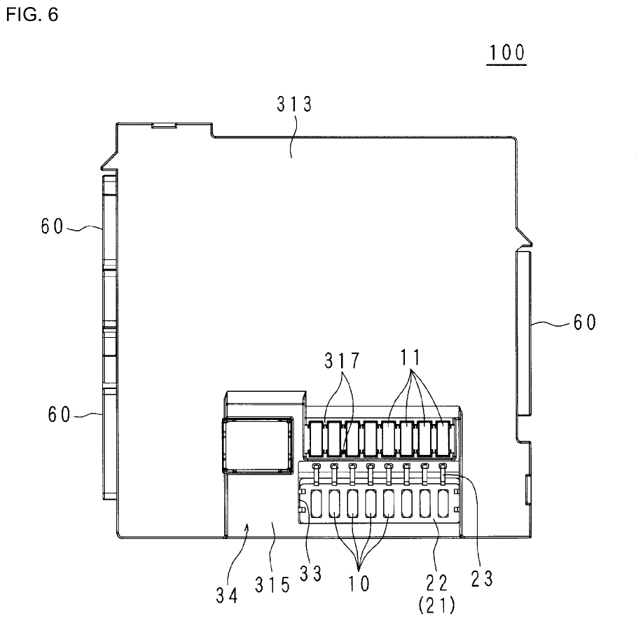

FIG. 6 is a plane view of the electrical junction box 100 according to Embodiment 2.

The electrical junction box 100 according to Embodiment 2 further includes an outlet 33 formed in the bottom 315. The outlet 33 penetrates a ceiling plate 313 in the thickness direction, and is formed at a position matching the positions of the first part 22 and the holding members 23, when viewed in the thickness direction of the case member 30. The outlet 33 is used for a user to check whether or not any fixed fuse 10 has been blown out, and replace the first part 22.

Similar to Embodiment 1, since the plurality of fixed fuses 10 are lined up, the outlet 33 has the shape of a rectangle whose longitudinal direction conforms to the direction in which the plurality of fixed fuses 10 are lined up. The long-side dimension of the outlet 33 is slightly larger than the long-side dimension of the first part 22. Also, the short-side dimension of the outlet 33 is sufficiently larger than the short-side dimension of the first part 22. All of the fixed fuses 10 (the first part 22) and the holding members 23 are exposed to the outside of the case member 30 via the outlet 33.

Accordingly, in the electrical junction box 100 according to Embodiment 2, the user can check, through the outlet 33, whether or not any fixed fuse 10 has been blown out. Also, when any fixed fuse 10 has been blown out, the user can handle the blowout by replacing the first part 22. Accordingly, it is possible to repair the electrical junction box 100 at low cost and easily, making it also possible to prevent waste of resources.

Also, in the electrical junction box 100 according to Embodiment 2, when it is found that any fixed fuse 10 has been blown out, the user can insert a certain tool through the outlet 33 to disengage the holding members 23, and can remove and replace the first part 22. Therefore, it is possible to save time and effort to disassemble the case member 30 for replacement of the fixed fuse 10 (the first part 22) and the like, and perform such replacement promptly.

Furthermore, in the electrical junction box 100 according to Embodiment 2, the short-side dimension of the outlet 33 is sufficiently larger than the short-side dimension of the first part 22, and the first part 22 and the holding members 23 are exposed to the outside of the case member 30 via the outlet 33. Accordingly, the user can easily perform an operation of disengaging the holding members 23 via the outlet 33.

In the electrical junction box 100 according to Embodiment 2, the short-side dimension (width) of the outlet 33 is not limited to that described above. It is sufficient that the short-side dimension of the outlet 33 is sufficiently larger than the short-side dimension of the first part 22 to the extent such that the first part 22 and the holding members 23 are exposed via the outlet 33. For example, the short-side dimension of the outlet 33 is preferably at least 1.5 times as large as the short-side dimension of the first part 22.

The same reference numerals are given to the same components as those of Embodiment 1, and detailed descriptions thereof are omitted.

### Embodiment 3

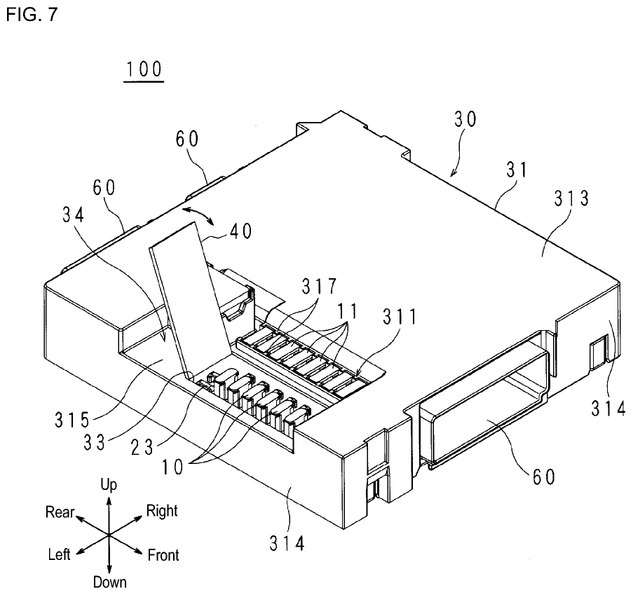

FIG. 7 is a perspective view illustrating an outer appearance of an electrical junction box 100 according to Embodiment 3.

Similar to Embodiment 1, the electrical junction box 100 according to Embodiment 3 includes a case member 30, and the case member 30 includes a substrate 21, a plurality of replaceable fuses 11 held on the substrate 21 so as to be detachable, and a plurality of fixed fuses 10 fixed to the substrate 21 by soldering.

Also, similar to Embodiment 1, the substrate 21 is constituted by a first part 22 and a second part 24, and the first part 22 is held on the second part 24 by holding members 23 (see FIG. 2), and is electrically connected to the second part 24.

Furthermore, a replacement window 311 is formed in a bottom 315 of the case member 30 at a position matching the positions of the plurality of replaceable fuses 11 when viewed in the thickness direction (up-down direction) of the case member 30.

Also, an outlet 33 is formed in the bottom 315, the outlet 33 being used for a user to check whether or not any fixed fuse 10 has been blown out, and replace the first part 22. The outlet 33 is formed at a position matching the positions of the first part 22 and the holding members 23 when viewed in the thickness direction of the case member 30.

The outlet 33 has the shape of a rectangle whose longitudinal direction conforms to the direction in which the plurality of fixed fuses 10 are lined up, and the long-side dimension of the outlet 33 is slightly larger than the long-side dimension of the first part 22. Also, the short-side dimension of the outlet 33 is sufficiently larger than the short-side dimension of the first part 22. All of the fixed fuses 10 (the first part 22) and the holding members 23 are exposed to the outside of the case member 30 via the outlet 33.

The electrical junction box 100 according to Embodiment 3 includes a lid member 40 that covers the outlet 33 and can open and close. The lid member 40 is rectangular corresponding to the outlet 33, and has a dimension slightly larger than that of the outlet 33, for example. The lid member 40 is made of a resin or the same material as that of the case member 30.

On the bottom 315 of the case member 30, a hinge (not shown) for rotating the lid member 40 is provided in the region of the shot-side of the outlet 33. One of the short sides of the lid member 40 is coupled to the hinge, and the lid member 40 rotates about the axis of the hinge (see arrows in FIG. 7). By rotating in this way, the lid member 40 opens and closes the outlet 33.

In the electrical junction box 100 according to Embodiment 3 having the above-described configuration, since the outlet 33 is covered by the lid member 40, it is possible to prevent dust or the like from entering the case member 30 via the outlet 33.

Furthermore, since the lid member 40 can open and close, when it is found that any fixed fuse 10 has been blown out, the user can open the lid member 40, insert a certain tool through the outlet 33 to disengage the holding members 23, and replace the first part 22. Therefore, it is possible to save time and effort to disassemble the case member 30 for replacement of the fixed fuse 10 (the first part 22) and the like, and perform such replacement promptly.

A case where a hinge is provided in the region of the short side of the outlet 33 has been described as an example, but the present disclosure is not limited to this case. Such a hinge may also be provided in the region of the long side of the outlet 33. A configuration is also possible in which the lid member 40 has the same dimension as that of the outlet 33, and the lid member 40 can be fitted into the outlet 33.

The same reference numerals are given to the same components as those of Embodiment 1, and detailed descriptions thereof are omitted.

### Embodiment 4

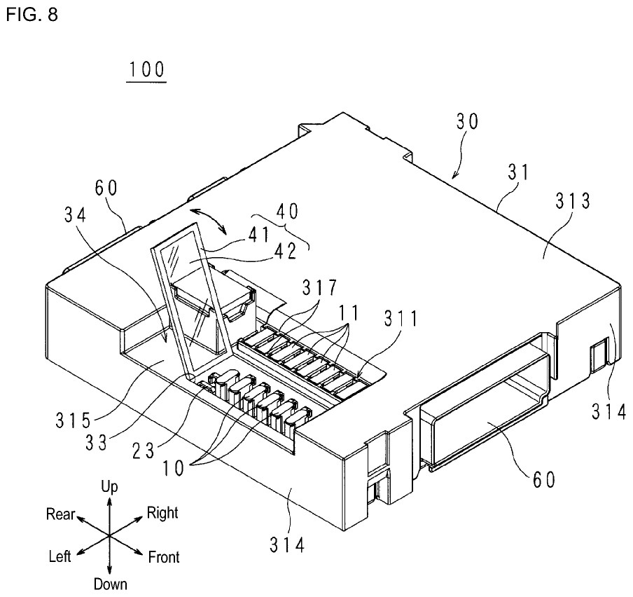

FIG. 8 is a perspective view illustrating an outer appearance of an electrical junction box 100 according to Embodiment 4.

Similar to Embodiment 1, the electrical junction box 100 according to Embodiment 4 includes a case member 30, and the case member 30 includes a substrate 21, a plurality of replaceable fuses 11 held on the substrate 21 so as to be detachable, and a plurality of fixed fuses 10 fixed to the substrate 21 by soldering.

Also, similar to Embodiment 1, the substrate 21 is constituted by a first part 22 and a second part 24, and the first part 22 is held on the second part 24 by holding members 23 (see FIG. 2), and is electrically connected to the second part 24.

Furthermore, a replacement window 311 is formed in a bottom 315 of the case member 30 at a position matching the positions of the plurality of replaceable fuses 11 when viewed in the thickness direction (up-down direction) of the case member 30. Also, an outlet 33 is formed in the bottom 315 at a position matching the positions of the first part 22 and the holding members 23 when viewed in the thickness direction of the case member 30. All of the fixed fuses 10 (the first part 22) and the holding members 23 are exposed to the outside of the case member 30 via the outlet 33.

The electrical junction box 100 according to Embodiment 4 includes a lid member 40 that covers the outlet 33 and can open and close. The lid member 40 is rectangular conforming to the outlet 33, and has a dimension slightly larger than that of the outlet 33, for example.

The lid member 40 includes a window part 42 (constituting a portion of the lid member 40) and a frame part 41. The window part 42 is located in the center of the lid member 40, is made of a resin, a glass, or the like, and is transparent or translucent. The frame part 41 is a rectangular frame and is made of a resin. The window part 42 is surrounded by the frame part 41.

On the bottom 315 of the case member 30, a hinge for rotating the lid member 40 is provided in the vicinity of the shot-side of the outlet 33. One of the short sides of the lid member 40 is coupled to the hinge, and the lid member 40 rotates about the axis of the hinge (see the arrows in FIG. 8). By rotating in this way, the lid member 40 opens and closes the outlet 33.

In the electrical junction box 100 according to Embodiment 4 having the above-described configuration, the user can immediately check, through the window part 42 of the lid member 40, whether or not any fixed fuse 10 has been blown out.

Also, since the outlet 33 is covered by the lid member 40, it is possible to prevent dust or the like from entering the case member 30 via the outlet 33.

Furthermore, since the lid member 40 can open and close, when it is found that any fixed fuse 10 has been blown out, the user can open the lid member 40, remove and replace the first part 22 through the outlet 33. Therefore, it is possible to save time and effort to disassemble the case member 30 for replacement of the fixed fuse 10 (the first part 22) and the like, and perform such replacement promptly.

Note that the electrical junction box 100 according to Embodiment 4 is not limited to the description above. For example, a configuration is also possible in which the lid member 40 does not have any frame part 41, but is constituted only by the window part 42.

The same reference numerals are given to the same components as those of Embodiment 1, and detailed descriptions thereof are omitted.

The embodiments disclosed herein are examples in all respects, and should be construed as non-limiting. The scope of the present disclosure is defined by the claims, and all modifications within the meaning and scope equivalent to the claims are intended to be included.

1. An electrical junction box comprising a substrate on which fuses are mounted,
wherein the substrate includes a first part to which the fuses are soldered, and a second part that excludes the first part, and
the first part and the second part are separable from each other.

2. The electrical junction box according to claim 1,
wherein the first part is arranged in an edge portion of the substrate.

3. The electrical junction box according to claim 1, further comprising a housing in which the substrate is housed, and
wherein the housing includes an outlet for removing the first part.

4. The electrical junction box according to claim 3, further comprising a lid member for opening and closing the outlet.

5. The electrical junction box according to claim 4, wherein the lid member is at least partially transparent.

6. The electrical junction box according to claim 3, wherein the outlet is formed at a position that corresponds to the first part.

7. The electrical junction box according to claim 1, further comprising a holding member for holding the first part on the second part, and wherein the holding member is configured to electrically connect the first part to the second part.

8. The electrical junction box according to claim 2, further comprising a housing in which the substrate is housed, and wherein the housing includes an outlet for removing the first part.

9. The electrical junction box according to claim 4, wherein the outlet is formed at a position that corresponds to the first part.

10. The electrical junction box according to claim 5, wherein the outlet is formed at a position that corresponds to the first part.

11. The electrical junction box according to claim 2, further comprising a holding member for holding the first part on the second part, and wherein the holding member is configured to electrically connect the first part to the second part.

12. The electrical junction box according to claim 3, further comprising a holding member for holding the first part on the second part, and wherein the holding member is configured to electrically connect the first part to the second part.

13. The electrical junction box according to claim 4, further comprising a holding member for holding the first part on the second part, and wherein the holding member is configured to electrically connect the first part to the second part.

14. The electrical junction box according to claim 5, further comprising a holding member for holding the first part on the second part, and wherein the holding member is configured to electrically connect the first part to the second part.

15. The electrical junction box according to claim 6, further comprising a holding member for holding the first part on the second part, and wherein the holding member is configured to electrically connect the first part to the second part.
